(19) United States
(12) Patent Application Publication
(10) Pub. No.: US 2026/0190894 A1
(43) Pub. Date: Jul. 2, 2026

(54) WAFER EDGE RING FOR STEALTH TRIM

(71) Applicant: Micron Technology, Inc., Boise, ID (US)

(72) Inventors: Jeremy E. Minnich, Boise, ID (US); Brandon P. Wirz, Boise, ID (US); Owen R. Fay, Meridian, ID (US); Andrew M. Bayless, Boise, ID (US)

(21) Appl. No.: 19/373,624

(22) Filed: Oct. 29, 2025

Related U.S. Application Data
(60) Provisional application No. 63/729,950, filed on Dec. 9, 2024.

(51) Int. Cl. H10P 54/20; H10W 80/00

(52) U.S. Cl. CPC H10P 54/20; H10W 80/00

(57) ABSTRACT

Wafer edge rings for stealth trimming and associated devices and methods are disclosed herein. In some embodiments, a method for preparing a wafer includes (i) applying a passivation layer onto a first wafer, (ii) defining a perimeter surface portion of the first wafer, (iii) bonding the first wafer to a second wafer, and (iv) trimming the first wafer along the perimeter surface portion. The passivation layer can be disposed between the first wafer and the second wafer. The perimeter surface portion of the first wafer may not bonded to the second wafer. Trimming the first wafer can remove an edge portion of the wafer along the perimeter surface portion.

### CROSS-REFERENCE TO RELATED APPLICATIONS

The present application claims priority to U.S. Provisional Patent Application No. 63/729,950, filed December 9, 2024, the disclosure of which is incorporated herein by reference in its entirety.

### TECHNICAL FIELD

The present technology generally relates to semiconductor device assemblies, and more particularly relates to wafer edge rings for stealth trimming.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are "packaged" to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

Features, aspects, and advantages of the presently disclosed technology may be better understood with regard to the following drawings.

FIGS. 1A and 1B illustrate bonding of two trimmed wafers.

FIGS. 2A and 2B are top and side views, respectively, of a wafer unit configured in accordance with embodiments of the present technology.

FIG. 3 is a partially schematic diagram illustrating manufacture of the wafer unit of FIG. 2A in accordance with embodiments of the present technology.

FIG. 4 is a partially schematic diagram illustrating one method of stealth dicing the wafer unit of FIG. 2A in accordance with embodiments of the present technology.

FIG. 5 is a partially schematic diagram illustrating another method of stealth dicing the wafer unit of FIG. 2A in accordance with embodiments of the present technology.

FIG. 6 is a partially schematic diagram illustrating grinding of the wafer unit of FIG. 2A in accordance with embodiments of the present technology.

FIG. 7 is a flowchart illustrating a method for preparing a wafer in accordance with embodiments of the present technology.

FIG. 8 is a flowchart illustrating another method for preparing a wafer in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### I. Overview

Embodiments of the present technology are directed to wafer units with edge rings that can facilitate stealth trimming of the wafer units, and associated systems and methods. Wafers are often trimmed to desired shapes and dimensions prior to bonding with other wafers. The trimming process, however, can result in the formation of debris, cracks or chipping in the wafer, and/or other artifacts that can compromise the wafer-over-wafer (WoW) bond. In particular, the bond adhesion along the edge of the wafers can vary, and a compromised WoW bond results in increased wafer stack defectivity and reduced yields.

Embodiments of the present technology address at least some of the above described issues related to wafer stack defectivity. For example, embodiments of the present disclosure include a method for preparing a wafer including (i) applying a passivation layer onto a first wafer, (ii) defining a perimeter surface portion of the first wafer, (iii) bonding the first wafer to a second wafer, and (iv) trimming the first wafer along the perimeter surface portion. The passivation layer can be disposed between the first wafer and the second wafer. The perimeter surface portion of the first wafer may not bonded to the second wafer. Trimming the first wafer can remove an edge portion of the wafer along the perimeter surface portion.

In some embodiments, another method for preparing a wafer includes (i) applying a passivation layer onto a first wafer to define a perimeter surface portion of the first wafer, (ii) bonding the first wafer to a second wafer, and (iii) trimming the first wafer along the perimeter surface portion. The perimeter surface portion may not be covered by the passivation layer or covered by a portion of the passivation layer of which a material property is altered to weaken a bond strength thereat. Trimming the first wafer can remove an edge portion of the wafer along the perimeter surface portion.

Embodiments of the present technology enable more precise wafer edge trimming compared to other trimming methods. As discussed further herein, because the edge of the wafer, after dicing and grinding, can be aligned with the edge of the passivation layer, the bond may be more uniform and the wafer can have reduced chipping around the wafer perimeter compared to other diced wafers. Therefore, embodiments of the present technology enable reduced wafer defectivity rates and increased wafer yields.

In the Figures, identical reference numbers identify generally similar, and/or identical, elements. Many of the details, dimensions, and other features shown in the Figures are merely illustrative of particular embodiments of the disclosed technology. Accordingly, other embodiments can have other details, dimensions, and features without departing from the spirit or scope of the disclosure. In addition, those of ordinary skill in the art will appreciate that further embodiments of the various disclosed technologies can be practiced without several of the details described below.

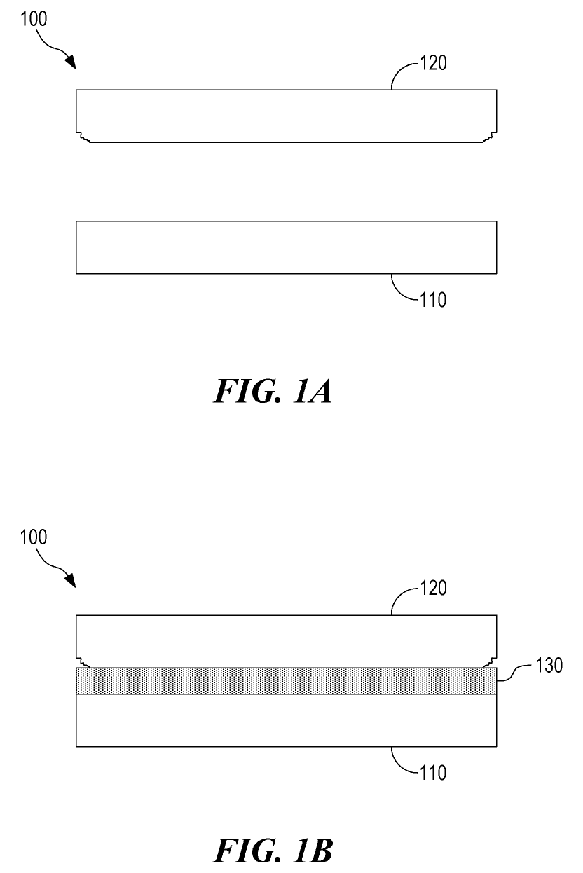

FIGS. 1A and 1B illustrate bonding of a first wafer 110 and a second wafer 120. More specifically, FIG. 1A is a side view of the first and second wafers 110, 120 prior to bonding, and FIG. 1B is a side view of the first and second wafers 110, 120 after bonding. Referring first to FIG. 1A, the second wafer 120 can be trimmed to desired shapes and dimensions prior to bonding. The trimming process can create debris and cracks, chipping, and/or uneven edges along the edge of one side of the second wafer 120. Referring next to FIG. 1B, the first wafer 110 and the second wafer 120 can be bonded via dielectric-dielectric (fusion) bonding, adhesive-based bonding, thermocompression bonding, hybrid bonding, and/or other suitable types of bonding. While FIG. 1B illustrates an intermediate layer 130 (e.g., an adhesive layer, a passivation layer, a metal layer), the first and second wafers 110, 120 can be bonded without the intermediate layer 130.

The debris created during the trimming process and/or the chipped or otherwise uneven bevels of the second wafer 120 can compromise the strength of the WoW bond, particularly along the edges. For example, the strength of the WoW bond can vary and/or be relatively weak along the edges and can lead to further defects in the wafer stack. In some cases, chemical mechanical planarization (CMP) can result in CMP roll-off, which can also lead to poor WoW bonding quality. Therefore, there is a need for wafers and associated methods that can be used to create wafer stacks with high and reliable WoW bond strength.

### II. Selected Embodiments of Wafer Units

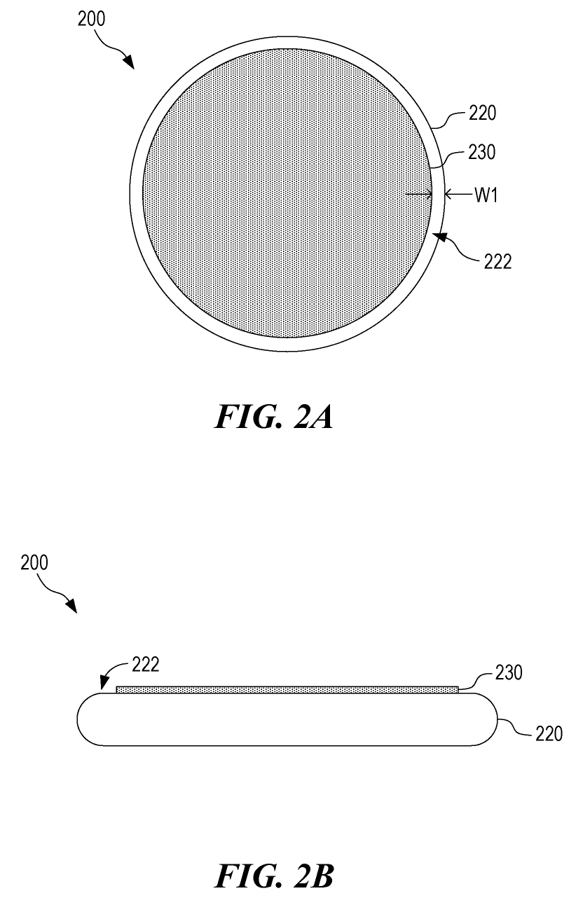

FIGS. 2A and 2B are top and side views, respectively, of a wafer unit 200 configured in accordance with embodiments of the present technology. Referring to FIGS. 2A and 2B together, the wafer unit 200 can include a wafer 220 and a dielectric or passivation layer 230. The wafer 220 can have a beveled disc form factor. The passivation layer 230 can include silicon dioxide, silicon nitride, or other suitable material, and can be applied onto one face of the wafer 220. More specifically, the passivation layer 230 can have a shape corresponding to the shape of the wafer 220 (e.g., circular) and can be sized smaller than the wafer 220 such that the wafer 220 has an edge or perimeter surface portion 222 that is not covered by the passivation layer 230. In the illustrated embodiment, the perimeter surface portion 222 is an edge ring having an annular shape and a width W1. The width W1 can be between 0.1–10 millimeters (mm), between 0.1–5 mm, between 0.5–5 mm, between 1–3 mm (e.g., 2 mm), or other dimensions. In other embodiments, however, the perimeter surface portion 222 can have other shapes.

As discussed further herein, upon bonding the wafer 220 to another wafer (e.g., a carrier wafer, a device wafer), the thickness of the passivation layer 230 can provide a gap between the two wafers. Thus, the perimeter surface portion 222 of the wafer 220 can remain unbonded. Subsequently, the wafer 220 can be trimmed and the perimeter surface portion 222 (and the lack of bonding thereto) can facilitate the removal of the wafer edge.

### III. Selected Embodiments of Methods for Manufacture

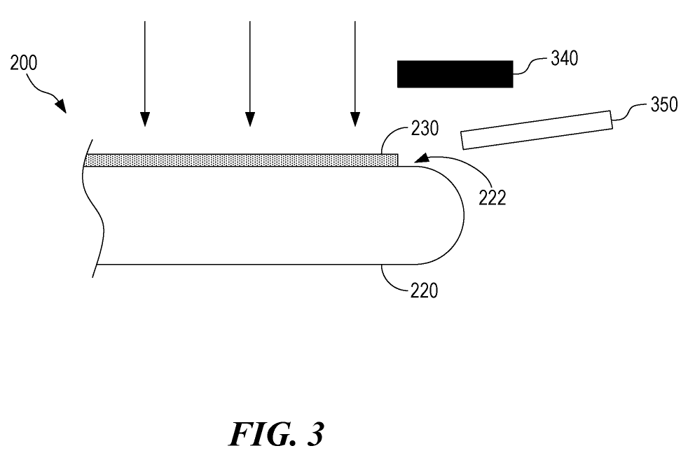

FIG. 3 is a partially schematic diagram illustrating manufacture of the wafer unit 200 in accordance with embodiments of the present technology. The passivation layer 230 can be applied onto the face of the wafer 220 via chemical vapor deposition, physical vapor deposition, spin coating, spray coating, and/or other techniques. The perimeter surface portion 222 without the passivation layer 230 thereon can be provided using one or more mechanisms. In some embodiments, a mask 340 (e.g., a photomask) can be used to block the application of the passivation layer 230 onto the perimeter surface portion 222. The mask 340 can be shaped and positioned to cover the desired perimeter surface portion 222.

In some embodiments, a tool 350 can be used to remove portions of the passivation layer 230 to expose the perimeter surface portion 222. For example, the tool 350 can apply a solvent, gas jets, plasma, and/or other edge bead removal agents to remove portions of the passivation layer 230 along the perimeter surface portion 222. In some embodiments, the tool 350 can be used to alter or modify a material property of the portion of the passivation layer 230 along the perimeter surface portion 222, such as to weaken a bonding strength thereof or thereat. For example, the tool 350 can be used to perform ion implantation, laser annealing, etching, doping, and/or the like onto the portion of the passivation layer 230 along the perimeter surface portion 222. It is appreciated that the mask 340, the tool 350, and/or other techniques can be used alone or in combination to provide the perimeter surface portion 222. Thus, the passivation layer 230 can define the perimeter surface portion 222, which can be configured to have a weaker bond strength than a remaining portion of the wafer 220 or the passivation layer 230.

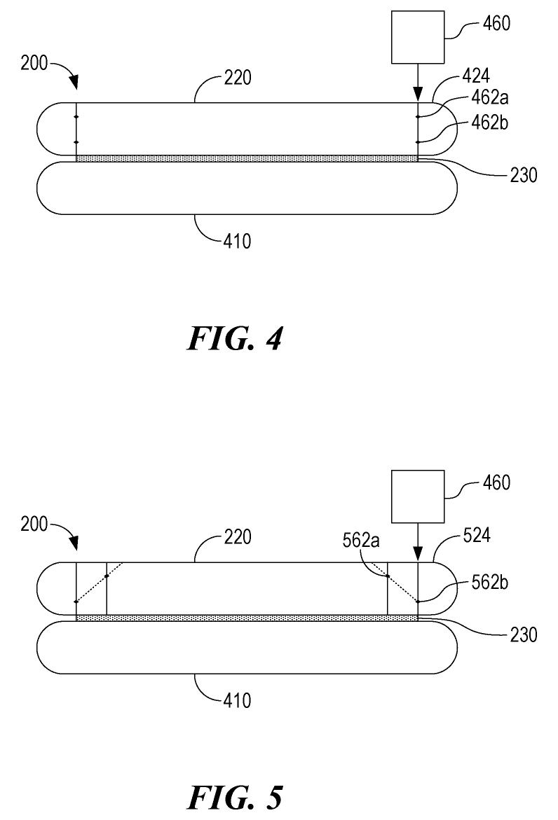

FIG. 4 is a partially schematic diagram illustrating one method of stealth dicing the wafer unit 200 in accordance with embodiments of the present technology. As shown, the wafer 220 can be bonded to another wafer 410 such that the passivation layer 230 is disposed between the wafer 220 and the wafer 410. The wafer 410 can be a carrier wafer, a logic wafer, a device wafer, and/or the like. The wafer 410 can have its own dielectric or passivation layer (not shown). When the wafer 220 is bonded to the wafer 410, the thickness of the passivation layer 230 can provide a gap (e.g., an air gap) therebetween at the perimeter surface portion 222.

A beam emitter 460 can be used to stealth dice the wafer 220 to a desired shape and size. The beam emitter 460 can be positioned to emit an energy beam (e.g., an infrared laser beam) through the wafer 220 along a direction substantially perpendicular to the wafer plane of the wafer 220, as shown. The beam emitter 460 can then be operated to focus the energy beam at one or more defined depths inside the wafer 220, thus creating one or more dislocations (e.g., silicon dislocations) in the wafer 220. In the illustrated embodiment, a first dislocation 462a at a first depth and a second dislocation 462b at a second depth greater than the first depth (collectively referred to as “the dislocations 462”) are formed while the beam emitter 460 is vertically aligned with the edge of the passivation layer 230. Therefore, the first and second dislocations 462a, 462b can be aligned along a vertical line extending from the edge of the passivation layer 230.

FIG. 5 is a partially schematic diagram illustrating another method of stealth dicing the wafer unit 200 in accordance with embodiments of the present technology. The beam emitter 460 can be used to form a first dislocation 562a at a first depth and a second dislocation 562b at a second depth greater than the first depth (collectively referred to as “the dislocations 562”). The second dislocation 562b can be vertically aligned with the edge of the passivation layer 230. However, unlike in the embodiment illustrated in FIG. 4, the dislocations 562 are laterally spaced apart such that the dislocations 562 are aligned along a diagonally extending line (e.g., angled at 45 degrees from the wafer plane of the wafer 220).

In some embodiments, the diagonally aligned dislocations 562 are formed by operating the beam emitter 460 to emit the energy beam vertically downward to create the first dislocation 562a at a first lateral position radially inward from the edge of the passivation layer 230, moving the beam emitter 460 laterally to a second lateral position vertically aligned with the edge of the passivation layer 230, and operating the beam emitter 460 to emit the energy beam vertically downward to create the second dislocation 562b at the second lateral position. In some embodiments, the diagonally aligned dislocations 562 are formed by operating the beam emitter 460 to emit the energy beam at the diagonal angle.

Referring to FIGS. 4 and 5 together, and as discussed in further detail below, the material forming the wafer 220 (e.g., silicon) can subsequently crack along the one or more dislocations, allowing edge portions 424 (FIG. 4) and 524 (FIG. 5) of the wafer 220 to break off and be removed. In some embodiments, the material can crack based on the lattice structure of the material (e.g., the silicon lattice structure). Notably, the perimeter surface portion 222 is not in contact with and/or bonded to the wafer 410 due to the gap therebetween. Otherwise, if the perimeter surface portion 222 is bonded to the wafer 410, the edge portions 424, 524 would remain bonded to the wafer 410, making removal thereof more difficult. In embodiments in which a tool (e.g., the tool 350 of FIG. 3) is used to modify material properties of the portion of the passivation layer 230 along the perimeter surface portion 222 to weaken the bond strength thereat, the edge portions 424, 524 of the wafer 220 can be removed due to the resulting weak or nonexistent bond notwithstanding the lack of a gap.

Thus, the size and break-off angle of the edge portions 424 that are to be removed can be controlled by controlling the positions (and thus the angle of the crack) and number (and thus the precision of the crack) of the dislocations. For example, three, four, five, or more dislocations can be formed along a line (or curve) extending at 30 degrees, 50 degrees, 70 degrees, or other non-orthogonal angles from the wafer plane of the wafer 220. In some embodiments, similar techniques can be employed to stealth dice or otherwise trim the wafer 410 in addition to the wafer 220. Also, it is appreciated that other trimming techniques (e.g., non-laser based) can be used to create the dislocations 462, 562 and/or otherwise facilitate removal of the edge portions 424, 524.

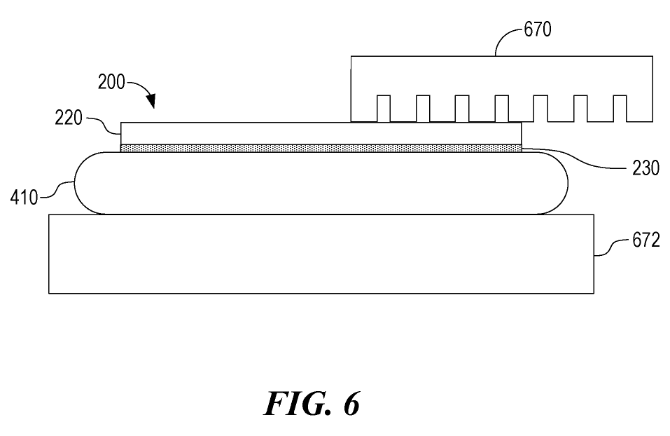

FIG. 6 is a partially schematic diagram illustrating grinding (e.g., back-grinding) of the wafer unit 200 in accordance with embodiments of the present technology. As shown, the wafer 410 and the wafer unit 200 bonded thereto can be placed on a grind chuck 672 or other support platform, and a grind wheel 670 or other grinding tool can be used to grind the back side of the wafer 220. As the grind wheel 670 thins the wafer 220, edge portions (e.g., the edge portions 424, 524) that are weakly connected to the remainder of the wafer 220 can break off and/or otherwise be removed. As discussed above with reference to FIGS. 4 and 5, the crack lines can be formed along the edge of the passivation layer 230. Therefore, once the edge portions are removed, the edge of the remaining wafer 220 can be aligned with the edge of the passivation layer 230. Subsequently, the wafer 220 may be separated from the wafer 410.

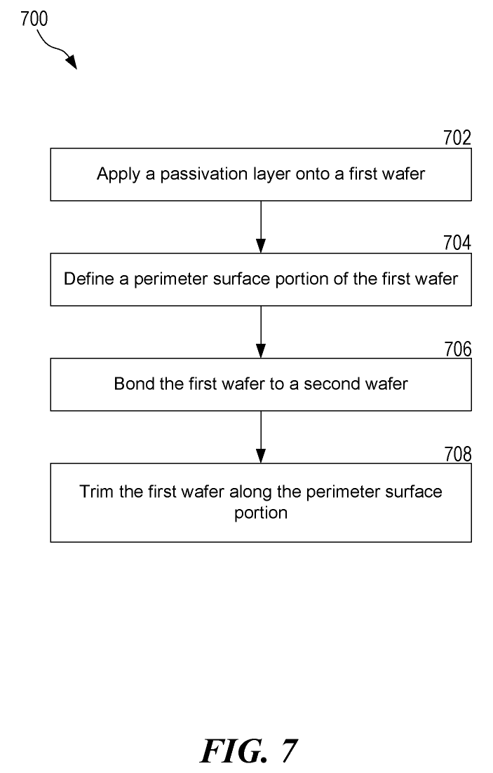

FIG. 7 is a flowchart illustrating a method 700 for preparing a wafer in accordance with some embodiments of the present technology. While the steps of the method 700 are described below in a particular order, one or more of the steps can be performed in a different order or omitted, and the method 700 can include additional and/or alternative steps. Additionally, although the method 700 may be described below with reference to the embodiments of the present technology described herein, the method 700 can be performed with other embodiments of the present technology.

The method 700 begins at block 702 by applying a passivation layer (e.g., the passivation layer 230) onto a first wafer (e.g., the wafer 220). The passivation layer can be applied via various deposition or other techniques.

At block 704, the method 700 continues by defining a perimeter surface portion (e.g., the perimeter surface portion 222) of the first wafer. The perimeter surface portion can be defined in various ways. For example, a photomask can be used to prevent application of the passivation layer onto the perimeter surface portion. In another example, a portion of the passivation layer along the perimeter surface portion can be removed via, e.g., performing edge bead removal of the portion. In yet another example, a material property of a portion of the passivation layer along the perimeter surface portion can be altered, thereby weakening a bond strength along the portion of the passivation layer along the perimeter surface portion. The material property can be altered by performing, e.g., at least one of ion implantation, laser annealing, etching, or doping to the portion of the passivation layer along the perimeter surface portion.

At block 706, the method 700 continues by bonding the first wafer to a second wafer (e.g., the wafer 410). The passivation layer can be disposed between the first wafer and the second wafer, and the perimeter surface portion of the first wafer may not bonded to the second wafer. In some embodiments, the first wafer is bonded to the second wafer to leave a gap between the first wafer and the second wafer along the perimeter surface portion.

At block 708, the method 700 continues by trimming the first wafer along the perimeter surface portion, thereby removing an edge portion (e.g., the edge portions 424, 524) of the wafer along the perimeter surface portion. In some embodiments, the first wafer is trimmed by focusing a laser beam at one or more points in the first wafer to form corresponding one or more dislocations (e.g., the dislocations 462, 562), and the one or more dislocations can define a path for a crack to form in the first wafer. The path can be substantially perpendicular to a wafer plane, non-orthogonal to the wafer plane, and/or formed based on a silicon (or other material) lattice structure of the first wafer. In some embodiments, trimming further includes grinding the first wafer, thereby allowing edge portions of the first wafer along the crack to break off of the first wafer.

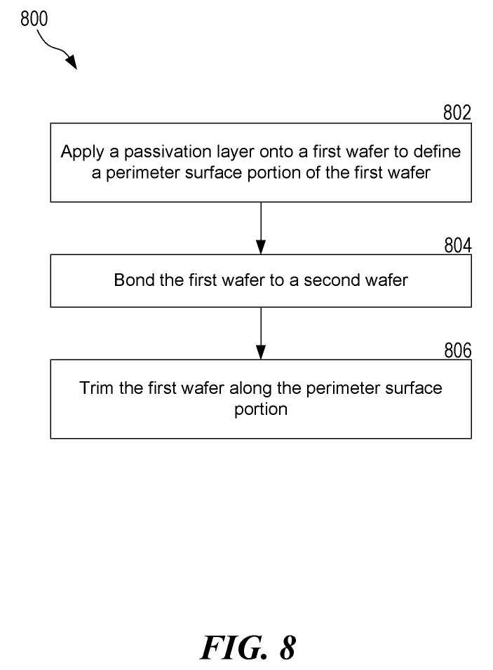

FIG. 8 is a flowchart illustrating another method 800 for preparing a wafer in accordance with some embodiments of the present technology. While the steps of the method 800 are described below in a particular order, one or more of the steps can be performed in a different order or omitted, and the method 800 can include additional and/or alternative steps. Additionally, although the method 800 may be described below with reference to the embodiments of the present technology described herein, the method 800 can be performed with other embodiments of the present technology.

The method 800 begins at block 802 by applying a passivation layer onto a first wafer to define a perimeter surface portion of the first wafer. The perimeter surface portion may (i) not covered by the passivation layer or (ii) covered by a portion of the passivation layer of which a material property is altered to weaken a bond strength thereat.

At block 804, the method 800 continues by bonding the first wafer to a second wafer. The passivation layer can be disposed between the first wafer and the second wafer. In some embodiments, the first wafer is bonded to the second wafer to leave a gap between the first wafer and the second wafer along the perimeter surface portion.

At block 806, the method 800 continues by trimming the first wafer along the perimeter surface portion, thereby removing an edge portion of the wafer along the perimeter surface portion. In some embodiments, trimming the first wafer is performed after bonding the first wafer to the second wafer.

Referring to FIGS. 2–8 together, embodiments of the present technology enable more precise wafer edge trimming compared to other trimming methods. Also, because the edge of the wafer 220, after dicing and grinding, can be aligned with the edge of the passivation layer 230, the bond may be more uniform and the wafer 220 can have reduced chipping around the wafer perimeter compared to other diced wafers. Therefore, embodiments of the present technology enable reduced wafer defectivity rates and increased wafer yields.

### IV. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing numerical values used in the specification and claims, are to be understood as being modified in all instances by the term “about.” The terms “about” and substantially” as used herein in the specification and/or the claims shall mean within 10% of the provided value or feature. Accordingly, unless indicated to the contrary, the numerical parameters set forth in the specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. Additionally, all ranges disclosed herein are to be understood to encompass any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

I/We claim:

1. A method for preparing a wafer, the method comprising:
applying a passivation layer onto a first wafer;
defining a perimeter surface portion of the first wafer;
bonding the first wafer to a second wafer, wherein the passivation layer is disposed between the first wafer and the second wafer, and wherein the perimeter surface portion of the first wafer is not bonded to the second wafer; and
trimming the first wafer along the perimeter surface portion, thereby removing an edge portion of the wafer along the perimeter surface portion.

2. The method of claim 1, wherein defining the perimeter surface portion comprises using a photomask to prevent application of the passivation layer onto the perimeter surface portion.

3. The method of claim 1, wherein defining the perimeter surface portion comprises removing a portion of the passivation layer along the perimeter surface portion.

4. The method of claim 3, wherein removing the portion of the passivation layer along the perimeter surface portion comprises performing edge bead removal of the portion.

5. The method of claim 1, wherein defining the perimeter surface portion comprises altering a material property of a portion of the passivation layer along the perimeter surface portion, thereby weakening a bond strength along the portion of the passivation layer along the perimeter surface portion.

6. The method of claim 5, wherein altering the material property comprises performing at least one of ion implantation, laser annealing, etching, or doping to the portion of the passivation layer along the perimeter surface portion.

7. The method of claim 1, wherein bonding the first wafer to the second wafer comprises leaving a gap between the first wafer and the second wafer along the perimeter surface portion.

8. The method of claim 1, wherein trimming the first wafer comprises focusing a laser beam at one or more points in the first wafer to form corresponding one or more dislocations, wherein the one or more dislocations define a path for a crack to form in the first wafer.

9. The method of claim 8, wherein the path defined by the one or more dislocations is aligned with an edge of the passivation layer.

10. The method of claim 8, wherein the path defined by the one or more dislocations is substantially perpendicular to a wafer plane of the first wafer.

11. The method of claim 8, wherein the path defined by the one or more dislocations is non-orthogonal to a wafer plane of the first wafer.

12. The method of claim 8, wherein the path defined by the one or more dislocations is formed based on a silicon lattice structure of the first wafer.

13. The method of claim 8, wherein trimming the first wafer further comprises grinding the first wafer, thereby allowing edge portions of the first wafer along the crack to break off of the first wafer.

14. The method of claim 1, wherein defining the perimeter surface portion comprises defining an annular shape of the perimeter surface portion.

15. The method of claim 1, wherein defining the perimeter surface portion comprises defining a width of the perimeter surface portion between 0.1–5mm.

16. A method for preparing a wafer, the method comprising:
applying a passivation layer onto a first wafer to define a perimeter surface portion of the first wafer, wherein the perimeter surface portion is (i) not covered by the passivation layer or (ii) covered by a portion of the passivation layer of which a material property is altered to weaken a bond strength thereat;
bonding the first wafer to a second wafer; and
trimming the first wafer along the perimeter surface portion, thereby removing an edge portion of the wafer along the perimeter surface portion.

17. The method of claim 16, wherein trimming the first wafer is performed after bonding the first wafer to the second wafer.

18. A wafer unit, comprising:
a wafer; and
a passivation layer disposed on the wafer, wherein the passivation layer defines a perimeter surface portion of the wafer configured to have a weaker bond strength than a remaining portion of the wafer.

19. The wafer unit of claim 18, wherein the perimeter surface portion is exposed and not covered by the passivation layer.

20. The wafer unit of claim 18, wherein a portion of the passivation layer along the perimeter surface portion has a material property altered to exhibit a weaker bond strength than a remaining portion of the passivation layer.
